(19) United States
(12) Patent Application Publication
(10) Pub. No.: US 2025/0185274 A1
(43) Pub. Date: Jun. 5, 2025

(54) HIGH VOLTAGE III-N DEVICES AND STRUCTURES WITH REDUCED CURRENT DEGRADATION

(71) Applicant: Transphorm Technology, Inc., Goleta, CA (US)

(72) Inventors: Davide Bisi, Goleta, CA (US); Geetak Gupta, Goleta, CA (US); Steven Wienecke, Goleta, CA (US); Brian Swenson, Santa Barbara, CA (US); David Michael Rhodes, Santa Barbara, CA (US); Umesh Mishra, Montecito, CA (US); Robin Christine Hwang, Goleta, CA (US)

(21) Appl. No.: 19/038,190

(22) Filed: Jan. 27, 2025

Related U.S. Application Data
(63) Continuation of application No. PCT/US2023/070891, filed on Jul. 25, 2023.
(60) Provisional application No. 63/392,074, filed on Jul. 25, 2022.

(51) Int. Cl. H10D 30/47; G01R 31/26; H10D 62/85; H10D 64/00; H10D 64/23; H10D 64/27

(52) U.S. Cl. CPC H10D 30/475; H10D 62/8503; H10D 64/112; H10D 64/256; H10D 64/411; G01R 31/2642

(57) ABSTRACT

Lateral III-N devices such as AlGaN/GaN HEMTs can have structures which serve to improve performance and reduce current degradation. The III-N device can include a conductive substrate and a III-N material structure that includes a III-N buffer layer, a III-N channel layer and a III-N barrier layer where a compositional difference induces a 2DEG channel therein. The first portion is in ohmic contact with the 2DEG channel and the second portion extends over a top surface of the III-N barrier layer and is in direct contact with the top surface of the III-N barrier layer. The device further includes a drain-to-substrate pinch-off voltage and a maximum rated drain-to-source operating voltage which is greater than the drain-to-substrate pinch-off voltage, and the 2DEG channel is fully depleted of charge below the second portion of the drain electrode when the III-N device is biased at or above the maximum rated drain-to-source operating voltage.

### CROSS-REFERENCE TO RELATED APPLICATIONS

This application is a continuation application and claims priority under 35 U.S.C. § 120 to International Application No. PCT/US2023/070891, filed on Jul. 25, 2023, which claims the benefit of priority under 35 U.S.C. § 119 (e) to Provisional Application No. 63/392,074, filed on Jul. 25, 2022. The disclosure of the prior applications are considered part of and are incorporated by reference in the disclosure of this application.

### TECHNICAL FIELD

The disclosed technologies relate to semiconductor devices, in particular III-Nitride transistors and switches.

### BACKGROUND

Currently, typical power semiconductor devices, including devices such as transistors, diodes, power MOSFETs and insulated gate bipolar transistors (IGBTs), are fabricated with silicon (Si) semiconductor material. More recently, wide-bandgap materials (SiC, III-N, III-O, diamond) have been considered for power devices due to their superior properties. III-Nitride or III-N semiconductor devices, such as gallium nitride (GaN) devices or AlGaN/GaN HEMT transistors, are now emerging as attractive candidates to carry large currents, support high voltages and provide very low on-resistance and fast switching times.

Although high voltage GaN HEMT transistors are beginning to be commercialized, thus far the design and the fabrication of III-N transistors with high figures of merit has proven difficult. Design improvements are needed to improve the size, efficiency, reliability and output characteristics of the devices in order to accelerate market adaptation.

### SUMMARY

Described herein are lateral III-N devices such as AlGaN/GaN HEMTs having structures which serve to improve performance and reduce current degradation.

In a first aspect, a III-N device is described. The III-N device can include a conductive substrate and a III-N material structure. The III-N material structure includes a III-N buffer layer, a III-N channel layer and a III-N barrier layer where a compositional difference induces a 2DEG channel therein. The device further includes a source electrode, a gate electrode electrically connected to the conductive substrate, and a drain electrode, where the drain electrode includes a first portion and a second portion. The first portion is in ohmic contact with the 2DEG channel and the second portion extends over a top surface of the III-N barrier layer and is in direct contact with the top surface of the III-N barrier layer. The device further includes a drain-to-substrate pinch-off voltage and a maximum rated drain-to-source operating voltage, where the maximum rated drain-to-source operating voltage is greater than the drain-to-substrate pinch-off voltage, and the 2DEG channel is fully depleted of charge below the second portion of the drain electrode when the III-N device is biased at or above the maximum rated drain-to-source operating voltage

In a second aspect a III-N device is described. The device includes a conductive substrate and a III-N material structure. The III-N material structure includes a III-N buffer layer, a III-N channel layer, and a III-N barrier layer, where the compositional difference between the III-N channel layer and the III-N barrier layer induces a 2DEG channel therein. The device further includes as source, gate, and drain electrode, where the drain comprises a first portion and a second portion. The first portion of the drain electrode is in ohmic contact with the 2DEG channel and the second portion of the drain electrode extends on a top surface of the III-N barrier layer is in direct contact with the top surface. The III-N device comprises a drain-to-substrate pinch-off voltage and a maximum rated drain-to-source operating voltage, where the maximum rated drain-to-source operating voltage is at least 50Vgreater than the drain-to-substrate pinch-off voltage. The device has a first on-state resistance when the drain-to-source voltage is held constant at a low voltage, wherein the device has a second on-state resistance upon the drain-to-substrate voltage being swept from the low voltage to the maximum rated drain-to-source voltage, held at said voltage for at least 2 min, and swept back to the low voltage, and the first on-state resistance is within 25% of the second on-state resistance.

In a third aspect a III-N device is described. The device includes a conductive substrate and a III-N material structure. The III-N material structure includes a III-N buffer layer, a III-N channel layer, and a III-N barrier layer, where the compositional difference between the III-N channel layer and the III-N barrier layer induces a 2DEG channel therein. The III-N buffer layer includes at least five distinct layers increasing sequentially from first side of the III-N buffer layer adjacent the substrate to a second side of the III-N buffer layer adjacent the III-N channel layer. The first layer is a AlN nucleation layer, the second layer is AlₓGa₁₋ₓN where 70%<x<90% with a thickness between 0.2 μm and 1.0 μm, the third layer is AlₓGa₁₋ₓN where 40%<x<70% with a thickness between 0.2 μm and 1.0 μm, the fourth layer is between 0.5 μm and 1.5 μm thick and includes a repetition of AlN/AlₓGa₁₋ₓN stacked layers, wherein the AlN layers are between 0.5 nm and 5 nm thick and the AlₓGa₁₋ₓN layers are between 10 nm and 50 nm thick and 5%<x<20%, the fifth layer is between 0.5 μm and 1.5 μm thick and includes a repetition of AlN/GaN stacked layers where the AlN layers are between 0.5 nm and 5 nm thick and the GaN layers are between 10 nm and 50 nm thick The device further includes a source electrode, a gate electrode, and a drain electrode, where the gate electrode is electrically connected to the conductive substrate and the 2DEG channel is not fully depleted of charge when the III-N device is biased at the maximum rated drain-to-source operating voltage.

Each of the electronic devices, transistors and methods described herein can include one or more of the following features. The device has a maximum rated drain-to-source operating voltage of greater than 600V and a drain-to-substrate pinch-off voltage of less than 600V or the device has a maximum rated drain-to-source operating voltage of at least 650V and a drain-to-substrate pinch-off voltage of 600V or less. The 2DEG channel is fully depleted of charge below the second portion of the drain electrode when the III-N device is biased at the maximum rated drain-to-source pinch-off voltage. The device is intentionally free of any dielectric or insulating material between the drain electrode and the III-N material structure. The device can include a gate dielectric layer formed between the top surface of the III-N barrier layer and the gate electrode, wherein the gate dielectric layer comprises a first end extending towards the drain electrode and a second end extending towards the source electrode, a separation between the first end and the drain electrode is between 0.1 μm and 2 μm, and the separation is filled with an insulating material with a different composition than the gate dielectric layer. The source electrode comprises a first portion and a second portion, the first portion is in ohmic contact with the 2DEG channel and the second portion extends over the top surface of the III-N barrier layer and is in direct contact with the top surface. When the drain-to-source voltage is at the maximum rated operating voltage, the 2DEG channel below the second portion of the drain electrode is depleted from a vertical electric field between the drain electrode and the conductive substrate. An Ips of the first on-state resistance is within 20% of an Ips of the second on-state resistance. The III-N material structure is less than 6 μm thick and the III-N material structure has a break down voltage of greater than 750V. The III-N material structure is formed on a conductive silicon substrate, and the first side of the III-N buffer layer is adjacent to the conductive silicon substrate.

As used herein, the terms III-Nitride or III-N materials, layers, devices, etc., refer to a material or device comprised of a compound semiconductor material according to the stoichiometric formula BwAl,InyGazN, where w+x+y+z is about 1 with 0 ≤w≤1, 0≤x≤1, 0≤y≤1, and 0≤z≤1. III-N materials, layers, or devices, can be formed or prepared by either directly growing on a suitable substrate (e.g., by metal organic chemical vapor deposition), or growing on a suitable substrate, detaching from the original substrate, and bonding to other substrates.

As used herein, two or more contacts or other items such as conductive channels or components are said to be “electrically connected” if they are connected by a material which is sufficiently conducting to ensure that the electric potential at each of the contacts or other items is intended to be the same, e.g., is about the same, at all times under any bias conditions.

As used herein, “blocking a voltage” refers to the ability of a transistor, device, or component to prevent significant current, such as current that is greater than 0.001 times the operating current during regular conduction, from flowing through the transistor, device, or component when a voltage is applied across the transistor, device, or component. In other words, while a transistor, device, or component is blocking a voltage that is applied across it, the total current passing through the transistor, device, or component will not be greater than 0.001 times the operating current during regular conduction. Devices with off-state currents which are larger than this value exhibit high loss and low efficiency, and are typically not suitable for many applications, especially power switching applications.

As used herein, a “depletion-mode device” refers to a transistor which has a negative threshold voltage and is considered to be in the “ON” state when the gate of the depletion-mode transistor is biased greater than the negative threshold voltage such that the device would be ON when the gate is biased at zero volts. An “enhancement-mode device” refers to a transistor which has a positive threshold voltage and is considered to be in the “OFF” state when the gate of the enhancement-mode transistor is biased at zero volts. The “on-resistance” of a transistor refers to the resistance between the source and drain contacts of the transistor when the transistor is biased in the ON state (i.e., RDS (ON)). As used herein, the on-resistance is measured when the device is considered to be in saturation-mode.

As used herein, a “high-voltage device”, e.g., a high-voltage switching transistor, HEMT, bidirectional switch, or four-quadrant switch (FQS), is an electronic device which is optimized for high-voltage applications. That is, when the device is off, it is capable of blocking high voltages, such as about 300V or higher, about 600V or higher, or about 1200V or higher, and when the device is on, it has a sufficiently low on-resistance (RON) for the application in which it is used, e.g., it experiences sufficiently low conduction loss when a substantial current passes through the device. A high-voltage device can at least be capable of blocking a voltage equal to the high-voltage supply or the maximum voltage in the circuit for which it is used. A high-voltage device may be capable of blocking 300V, 600V, 1200V, 1700V, 2500V, 3300V or other suitable blocking voltage required by the application. In other words, a high-voltage device can block all voltages between 0V and at least Vmax, where Vmax is the maximum voltage that can be supplied by the circuit or power supply, and Vmax can for example be 300V, 600V, 1200V, 1700V, 2500V, 3300V or other suitable blocking voltage required by the application. For a bidirectional or four quadrant switch, the blocked voltage could be of any polarity less a certain maximum when the switch is OFF (+Vmax such as +300V or +600V, +1200V and so on), and the current can be in either direction when the switch is ON.

As used herein, an electrode refers to the metal layers within a device or transistor which are connected to either the source, gate or drain of the device. A “pad” such as a “source pad, drain pad, or gate pad” refer to the uppermost un-passivated portion of the electrode which is used to electrically connect the device or transistor to the package e.g., with solder, epoxy, wire-bonds and/or metal clips.

As used herein, a “III-N device” is a device based on or essentially including III-N materials, including III-N heterostructures. The III-N device can be designed to operate as a transistor or switch in which the state of the device is controlled by a gate terminal or as a two terminal device that blocks current flow in one direction and conducts in another direction without a gate terminal. The III-N device can be a high-voltage device suitable for high voltage applications. In such a high-voltage device, when the device is biased off (e.g., the voltage on the gate relative to the source is less than the device threshold voltage), it is at least capable of supporting all source-drain voltages less than or equal to the high-voltage in the application in which the device is used, which for example may be 100V, 300V, 600V, 1200V, 1700V, 2500V, or higher. When the high voltage device is biased on (e.g., the voltage on the gate relative to the source or associated power terminal is greater than the device threshold voltage), it is able to conduct substantial current with a low on-voltage (i.e., a low voltage between the source and drain terminals or between opposite power terminals). The maximum allowable on-voltage is the maximum on-state voltage that can be sustained in the application in which the device is used.

As used herein, a “III-polar” or “group-III polar” III-N material is a III-N material for which the group-III face (i.e., the [0 0 0 1] face) is opposite the substrate on which the material is grown. In a “III-polar” or “group-III polar” lateral III-N device, at least some of the device contacts (e.g., the source and/or drain contacts) are typically formed on a [0 0 0 1] face of the III-N material (e.g., on a side opposite the [0 0 0-1] face).

As used herein, an “N-polar” III-N material is a III-N material for which the Nitrogen face (i.e., the [0 0 0-1] face) is opposite the substrate on which the material is grown. In an “N-polar” lateral III-N device, at least some of the device contacts (e.g., the source and/or drain contacts) are typically formed on a [0 0 0-1] face of the III-N material (e.g., on a side opposite the [0 0 0 1] face).

As used herein, a “regrown” III-N layer structure or III-N material structure, refers to an additional material deposition process which is performed after previous material deposition processes. Between subsequent growth and regrowth processes, the device can be unloaded from the deposition tool and the vacuum environment can be interrupted. As such, a regrown III-N material structure can require a separate insertion into the III-N material structure deposition equipment from the initial III-N material structure insertion. For example, a regrown III-N layer can be deposited after a removal of at least a portion of an initial III-N material structure. The removal of a portion of the initial III-N material structure typically occurs in an environment outside the primary III-N material structure deposition equipment.

The terms “over,” “under,” “between,” and “on” as used herein refer to a relative position of one layer with respect to other layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

The details of one or more disclosed implementations of the subject matter described in this specification are set forth in the accompanying drawings and the description below. Additional features and variations may be included in the implementations as well. Other features, aspects, and advantages will become apparent from the description, the drawings and the claims.

### DESCRIPTION OF DRAWINGS

FIGS. 1A-1C are cross-sectional views of a III-N device.

FIG. 2A is a cross-sectional view of III-N device with an engineered III-N buffer layer.

FIG. 2B is a test circuit schematic used to measure current degradation.

FIGS. 2C and 2D show graphical data comparing measured results of back-gating measurements of III-N devices.

FIG. 2E is a box-plot diagram of a III-N device on-state resistance during HTRB.

FIG. 3A is a cross-sectional of a III-N device.

FIG. 3B shows graphical data of back-gating measurements of a III-N device.

FIG. 3C shows graphical data comparing the on-resistance of III-N devices after HTRB.

FIGS. 4A and 4B are cross-sectional views of III-N device with n-type ohmic contacts.

FIG. 5 is a cross-sectional view of a III-N device with two 2DEG channels.

FIG. 6 is a cross-sectional view of a III-N device with p-type electrode contacts.

FIG. 7 is a cross-sectional view of a III-N device with an insulating substrate.

FIGS. 8 (a)-(d) show a method of manufacturing a III-N device.

FIGS. 9 (a)-(d) show a method of manufacturing a source/drain electrode.

FIG. 10A is a cross-sectional view of a III-N device.

FIG. 10B shows graphical data of measured results of back-gating measurements of III-N device 110.

### DETAILED DESCRIPTION

Described herein are lateral III-N devices such as AlGaN/GaN HEMTs. These devices have structures which serve to improve performance and reduce current degradation, particularly when the devices are operated at or near the maximum voltage rating of the device. III-N power devices can have superior performance compared to their silicon counterparts, due to the very high conductivity of the two-dimensional electron gas (2DEG) channel inherent within lateral III-N devices, such as the AlGaN/GaN HEMT device. However, the performance and reliability of these devices can further be improved by eliminating or reducing a phenomenon known as current collapse during power switching operation. Current collapse can be caused by electron trapping which can occur in/on the device layers or buried within the III-N material structure. When the gate of the device is biased in the off-state, electrons can become trapped. These trapped electrons cannot quickly be removed with the sudden change of the gate voltage to the on-state. These trapped electrons will deplete an equal portion of the 2DEG channel charge. This will cause the device channel on-state resistance to increase under switching conditions, and overall current level degradation is observed.

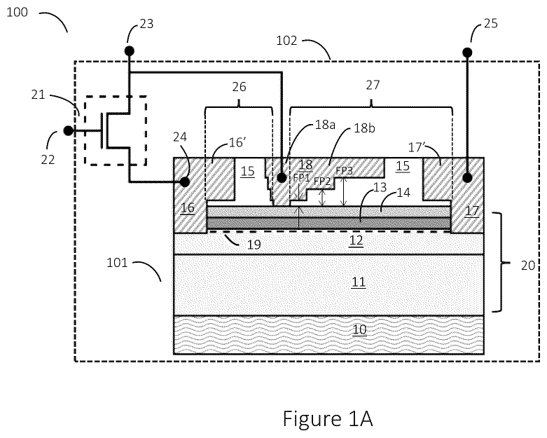

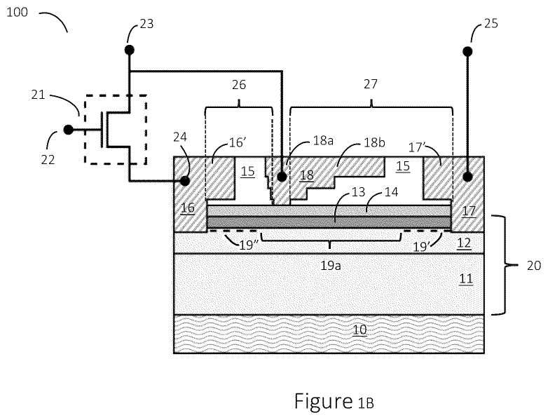

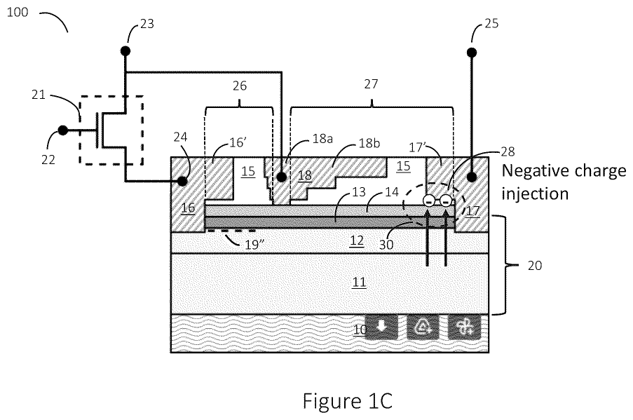

A cross-sectional view of a high-voltage III-N device 101 is shown in FIG. 1A, such as a AlGaN/GaN HEMT device. III-N device 101 can be an enhancement-mode device (i.e., normally-off) or a depletion-mode device (i.e., normally-on). In the case that device 101 is a depletion-mode device (D-mode), device 101 can be in a cascode configuration with a low-voltage enhancement-mode device 21 (e.g., a silicon-FET), to form a normally-off hybrid device 100 which can operate in a similar manner as a single enhancement-mode III-N device.

The III-N device 101 of FIG. 1A includes a III-N material structure 20, for example a combination of GaN and AlGaN, grown on a suitable substrate 10, which can be an electrically conductive semiconductor such as silicon (e.g., p-type or n-type Si), GaN or any other sufficiently electrically conductive substrate. For example, the substrate can be doped p-type with a hole concentration greater than 1×10¹⁹ holes/cm³, or the substrate can be doped n-type with an electron concentration greater than 1×10¹⁹ electrons/cm⁻³. The substrate can have high thermal conductivity or low thermal conductivity; in the case of a low thermal conductivity substrate, the substrate can be thinned to improve thermal dissipation. The substrate can have a similar or different lattice constant and/or thermal expansion coefficient than that of any of the material layers of the III-N material structure 20.

The III-N material structure 20 can include a III-N buffer layer 11, for example GaN or AlGaN, grown over the substrate 10. The buffer layer 11 can be rendered insulating or substantially free of unintentional n-type mobile carriers by including dislocations or point defects in the layer, or by doping the layer with compensating elements, such as Fe, C, and/or Mg. The buffer layer can have a substantially uniform composition throughout, or the composition can vary. For example, in some implementations the buffer layer is compositionally graded, such as by grading the aluminum composition in the buffer layer (e.g., the substrate can be AlxG1-xN with x varying throughout the substrate). In other implementations, the buffer layer is formed of a “superlattice” structure which comprises alternating layers of GaN and Al (x) Ga (1-x) N. The thickness and composition of the buffer layer 11 can be optimized for high-voltage applications. That is, the buffer layer is capable of blocking a voltage equal and/or greater than the high-voltage supply or the maximum voltage in the circuit for which it is used. For example, the buffer layer 11 may be capable of blocking a voltage in the vertical direction of greater than 600V, 900V, or 1200V between the drain electrode 17 and the substrate 10. The thickness of the buffer layer 10 can be greater than 4 μm, for example the III-N buffer layer can have a thickness between 5 μm and 8 μm.

The III-N material structure can further include a III-N channel layer 12 (e.g., GaN) over the III-N buffer layer 11, and a III-N barrier layer 13 (e.g., AlGaN, AlInN, or AlGalnN) over the III-N channel layer 12. The bandgap of the III-N barrier layer 13 is greater than that of the III-N channel layer 12. The III-N channel layer 12 has a different composition than the III-N barrier layer 13, and the thickness and composition of the III-N barrier layer 12 is selected such that a two-dimensional electron gas (2DEG) channel 19 (indicated by the dashed line in FIG. 1A) is induced in the III-N channel layer 12 adjacent the interface between layers 13 and 12. When device 101 is a depletion-mode device, the 2DEG channel 19 extends continuously between the source electrode 16 and the drain electrode 17 when zero voltage bias is applied to the device. The III-N barrier layer 13 can have a first side and a second side, where the first side is adjacent to the III-N channel layer 12, and the second side is opposite the first side.

Typically, III-N high electron mobility transistors (HEMTs) are formed from epitaxial (i.e., epi) III-N material structures grown by molecular beam epitaxy (MBE) or metalorganic chemical vapor deposition (MOCVD) in a reactor or other techniques. The III-N material structures can be grown in a group-III polar (e.g., Ga-polar) orientation, such as the [0 0 0 1] (C-plane) orientation, as shown in FIG. 1A. That is, the source, gate, and drain electrodes of the HEMT are formed over the group-III face (e.g., [0 0 0 1] face) of the III-N material structure, which is typically on an opposite side of the III-N material structure from the substrate on which the III-N layers are formed.

Alternatively, III-N HEMTs can be formed on III-N material structures grown in an N-Polar (i.e., N-face) orientation, such as the [0 0 0-1] orientation. In this case, the source, gate, and drain electrodes of the HEMT are formed over the N-face (e.g., -1] face) of the III-N material structure. Here, the III-N material structure can include a III-N barrier layer over the III-N buffer layer, and a III-N channel layer 12 over the III-N barrier layer 13. The bandgap of the III-N barrier layer 13 is greater than that of the III-N channel layer 12 and the thickness and composition of the III-N barrier layer 13 is selected such that a two-dimensional electron gas (2DEG) channel 19 is induced in the III-N channel layer 12 adjacent the interface between III-N channel layer 12 and the III-N barrier layer 13. N-polar III-N materials have polarization fields with opposite direction than group-III polar III-N materials, thus can enable the implementation of III-N devices which cannot be fabricated using group-III polar structures.

A gate dielectric layer 14 is grown or deposited over the top surface of the III-N material structure 20 and is formed in direct contact with the second side of the III-N barrier layer 14. The gate dielectric 14 can, for example, be formed of or include Aluminum Oxide (Al₂O₃), Silicon Dioxide (SiO₂), SiₓN_{y}, Al₁₋ₓSiₓN, Al₁₋ₓSiₓO, Al₁₋ₓ SiₓON or any other wide bandgap insulator.

A source electrode 16 and a drain electrode 17 are formed on a side of the device 101 opposite the substrate 10, such that the device 101 is characterized as a lateral III-N device (i.e., the source and drain are on the same side of the device and current flows through the device laterally between the source 16 and the drain 17). The source electrode 16 and the drain electrode 17 are in ohmic contact and electrically connected to the device 2DEG channel 19 that is formed in layer 12. The source and drain electrodes 16, 17, e.g., source and drain electrodes, can be formed by metal stacks. A recess can be formed in the III-N barrier layer 13 to allow for improved ohmic contact of the source and drain electrodes 16, 17 to the 2DEG channel 19. The metal stacks can be Ti/Al/Ni/Au, Ti/Al, or other suitable metals. The source and drain electrodes 16, 17 can be formed by sputtering and dry etch processing or other techniques such as metal evaporation and post-deposition annealing processes.

An insulating layer 15 can be formed over the gate dielectric layer 14 layer which is shown as a single layer. It can alternatively be formed out of several layers deposited during different processing steps to form a single combined insulator layer 15. Insulating layer 15 can be formed of SiN, SiON, SiO2 or other appropriate insulating material.

A gate recess is formed in the insulating layer 15 exposing a top surface of the gate dielectric layer 14. A gate electrode 18 (e.g., a gate contact) can be at least partially formed in the recess where a portion 18a of the gate electrode 18 is in direct contact with the top surface of the gate dielectric layer 14. The gate recess can include multiple steps extending towards the drain electrode 17 where the gate metal is formed over the steps to create a field plate 18b; the field plate 18b is vertically separated from the gate dielectric layer 14 by a portion, e.g., a stepped portion, of the insulating layer 15. The field plate 18b can help to manage the electric field in the drain-side access region. Effective electric field management can require multiple field plates. For example, the field plate 18b includes at least 3 different step heights (i.e., FP1, FP2, FP3), each increasing in height as the field plate extends towards the drain 17. The gate electrode 18 can be formed of suitable conducting materials such as metal stacks, e.g., titanium/aluminum (Ti/Al) or nickel/gold (Ni/Au), and can be deposited by metal evaporation or sputtering or chemical vapor deposition or various atomic layer depositions (ALD). The gate electrode 18 may alternatively be another conductive material or material stack including one or more materials having a large work function, such as a semiconductor material having a large work function (e.g., p-type poly-silicon, indium tin oxide, tungsten nitride, indium nitride, or titanium nitride).

When device 101 is a depletion-mode device, the dielectric layer 14 is formed between the gate electrode 18 and the III-N barrier layer 13. The thickness of the dielectric layer 14 determines the threshold voltage (i.e., VTH) of the device, such that when the thickness of the dielectric layer 14 is increased, the threshold voltage of device 101 becomes more negative. Alternatively, the gate recess can extend through the gate dielectric layer 14 such that the gate electrode 18 is in contact or recessed within the III-N material structure 24 (not shown) in order to create an enhancement-mode device.

As previously mentioned, when device 101 is a depletion-mode device, it can be arranged in a cascode configuration with a low-voltage enhancement-mode FET device 21 to form a hybrid device 100. The hybrid device 100 can be arranged and assembled into a discrete electronic component package 102. The electronic component package 102 can have at least three terminals. The first terminal 25 is electrically connected to the drain electrode 17. The second terminal 23 is electrically connected to the source of the FET device 21 and the gate electrode 18 of device 101. The third terminal 22 of the device is electrically connected to the gate of the FET device 21.

The source electrode 16 and the drain electrode 17 can be formed on the III-N device 101 with a variety of techniques. One common method is to deposit a continuous layer of ohmic metal (e.g., by sputter deposition) over the top surface of the device 101. Next the ohmic metal layer is patterned with a photoresist to cover and protect the source and drain electrode area and the remaining unprotected metal layer is etched off (e.g., by a dry-etch process) to form the source and drain electrodes 16 and 17.

Due to limitations in photolithography tolerances and etching techniques, typically, extending portions of the source and drain electrode remain over the gate dielectric layer 14 and/or the insulating layer 15. As seen in FIG. 1A, an extending drain electrode portion 17′extends towards the gate electrode 18 into the drain-side access region 27 and an extending source electrode portion 16′ extends towards the gate electrode 18 into the source-side access region 26. Typically for power devices fabricated in traditional CMOS fabs, the extending portions 16′ and 17′ can range between 0.25 μm and lum in length (along the channel length). As seen in FIG. 1A, a portion of gate dielectric layer 14 and a portion of insulating layer 15 are formed between the drain electrode extending portion 17′ and the III-N barrier layer 12. Also, a portion of gate dielectric layer 14 and a portion of insulating layer 15 are formed between the source electrode extending portion 16′ and the III-N barrier layer 12.

In some configurations, a portion of insulating layer 15 may not be present below the extending electrode portions 16′ or 17′. In such configurations, the bottom surfaces of extending portions can be in direct contact with the top surface of the dielectric layer 14. For example, if the dielectric layer 14 is formed by in-situ MOCVD SiN, then the thickness of the SiN under the drain overhang 17′ would be roughly equal to the thickness of the MOCVD SiN layer 14. However, maintaining a high integrity of the MOCVD SiN layer is an important factor in device performance. One way to maintain the gate dielectric integrity is to deposit a sacrificial etch stopping SiN layer on top of the gate dielectric layer 14. One manufacturing technique is to use an etch stopping layer that is approximately equal to the step height of the first field plate (i.e., FP1) of the multiple field plate system 18b. In this scenario, the thickness of the portion of insulating layer 15 and the dielectric layer 14 below the drain overhang 17′ would be roughly equal to the thickness of the SiN under FP1 plus the gate dielectric 14 thickness. The thickness of the portion of insulating layer 15 and the dielectric layer 14 below the drain overhang 17′ can be 200 nm, 100 nm or less.

For the purpose of this specification, the source-side access region 26 is defined as the region, measured at the plane of the top surface of the dielectric layer 14, between the portion of source electrode 16 in contact with the 2DEG channel 19 and the portion of gate electrode 18a in contact with the gate dielectric layer 14, as shown in FIG. 1A. Similarly, the drain-side-access region 27 is defined as the region, measured at the plane of the top surface of the dielectric layer 14, between the portion of the gate electrode 18a in contact with the gate dielectric layer and the portion of drain electrode 17 in contact with the 2DEG channel 19, as shown in FIG. 1A.

Referring to FIG. 1B, when the III-N device 101 is a depletion-mode device, it can operate as follows: the gate electrode 18 and substrate 10 are electrically connected to circuit ground. The source electrode 16 is biased above the gate-to-source threshold voltage (VTH) of the III-N device 101, the 2DEG channel 19 becomes depleted forming a depletion region 19a below the gate electrode 18. The 2DEG channel 19 is no longer continuous between the source electrode 16 and the drain electrode 17, and the device is considered to be “OFF.” A positive drain-to-source voltage (i.e., VDS) is applied, as the drain-to-source voltage is further increased, the 2DEG channel 19 further depletes in the drain-side access region 27. As seen in FIG. 1B, a portion 19′ of the 2DEG channel can remain in the drain-side access region 27 proximal to the drain electrode 17 and a portion 19″ can remain in the sour-side access region 26 proximal to the source electrode 16.

When the drain-to-source voltage is sufficiently high, the 2DEG channel is fully depleted, i.e., the depletion region 19a reaches the drain electrode. The drain voltage at which the 2DEG is fully depleted depends on at least three factors: (1) the 2DEG charge density-higher 2DEG charge density requires higher drain voltage to reach full depletion, (2) the build-up of lateral electric field due to capacitive coupling between the drain electrode 17 and the gate electrode 18 determined by field-plate 18′ design and the length of the drain-side access region 27, and (3) the build-up of vertical electric-field due to the capacitive coupling between the drain electrode 17 and the conductive substrate 10, a phenomenon hereafter referred to as “back-gating.” The amount of 2DEG depletion caused by back-gating effect is determined by the applied drain-to-substrate potential (VD-SUB), the thickness and the resistivity uniformity of the III-N buffer layer 11. For a given applied VD-SUB and a given thickness of the III-N buffer layer 11, back-gating effect is stronger, i.e., there is more 2DEG depletion if a lower portion of the III-N buffer layer 11 is poorly insulating and less resistive than an upper portion of the III-N buffer layer 11. In this case, charge redistribution happens within the III-N buffer layer 11 and stronger capacitive coupling between the drain electrode 17 and the substrate 10 leads to more 2DEG depletion for a given applied VD-SUB. This effect is known in the literature as Maxwell-Wagner effect (see Digital Object Identifier 10.1109/TED.2017.2706090 and Digital Object Identifier 10.1109/TED.2006.877700). The drain-to-substrate voltage (VD-SUB) at which the 2DEG is fully depleted is referred thereafter as drain-to substrate pinch-off voltage (VD-SUBpinch-off).

If the III-N device 101 (specifically, the III-N buffer layer 11) is designed such that the drain-to-substrate pinch-off voltage (VD-SUBpinchoff) is less than the maximum rated source-to drain operating voltage of the device (VTR (DSS), the 2DEG channel 19/19′ (shown in FIG. 1B) will become fully depleted all the way to the drain electrode 17 if the VDS is biased at a voltage greater than VD-SUBpinch-off. VTR (DSS can be at least 50V higher than VD-SUBpinchoff. When this operating condition occurs (see FIG. 1C), the dielectric layer 14 and the insulating layer 15 are forward-biased and negative charge 28 is injected into the dielectric layer 14 and/or the insulating layer 15 below the drain electrode extending portion 17′ as shown in dashed region 30. Some of the negative charge 28 can become “trapped” in the insulating layers and is not easily removed. Next, when the III-N device 101 is switch “ON,” the 2DEG channel charge below extending portion 17′ is reduced resulting in an overall increase in device 101 on-resistance. Under high-voltage switching operation at or near the maximum drain-to-source voltage rating of the device, significant current collapse can be observed.

A possible solution to prevent the full 2DEG depletion (pinch-off) and mitigate charge trapping below the drain electrode extending portion 17′ is to increase the 2DEG charge density. However, this solution will cause other reliability issues associated with increased electric-field due to higher 2DEG charge, causing premature failures of the gate electrode 18 under lifetime operations. Therefore, other solutions may be desirable.

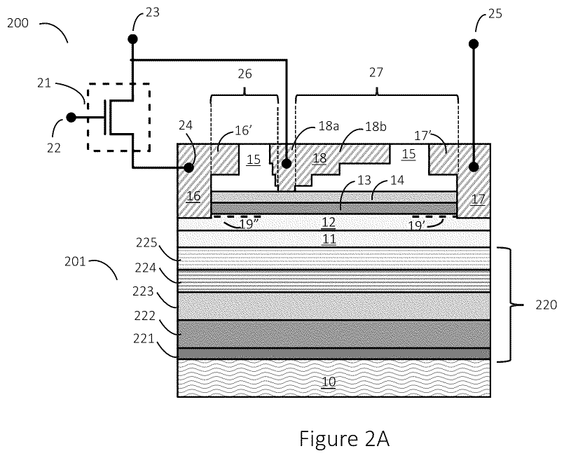

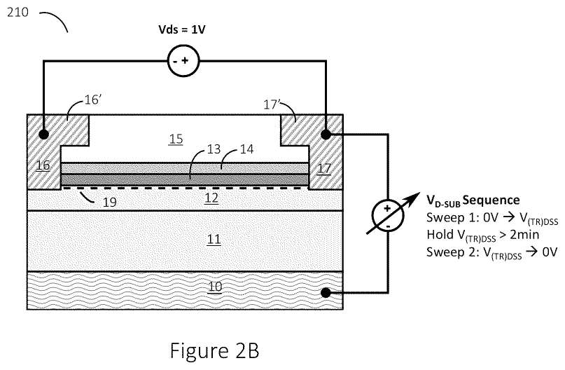

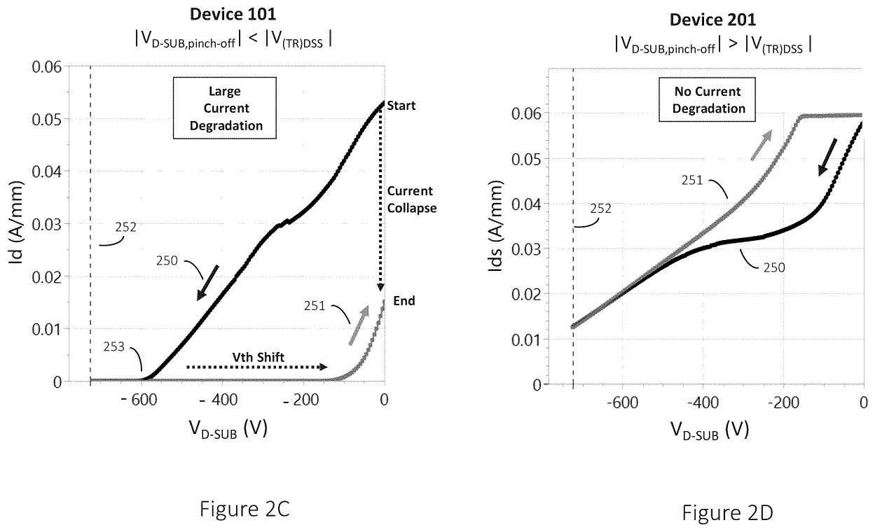

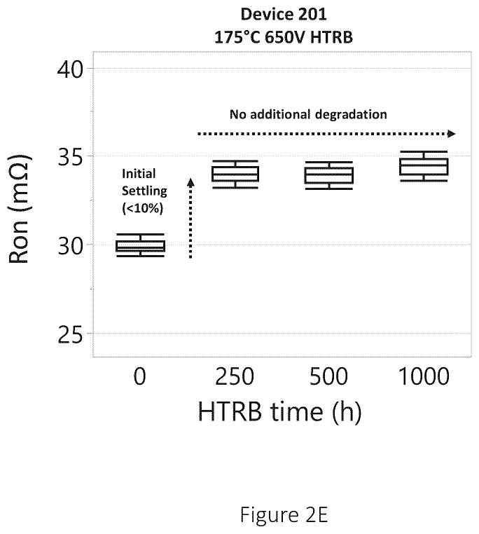

FIG. 2A shows a cross-sectional view of a III-N device 201 which is similar to the III-N device 101 of FIG. 1A. III-N device 201 can be an enhancement-mode device (i.e., normally-off) or a depletion-mode device (i.e., normally-on). In the case that device 201 is a depletion-mode device (D-mode), device 201 can be in a cascode configuration with a low-voltage enhancement-mode device 21 (e.g., a silicon-FET), to form a normally-off hybrid device 200 which can operate in a similar manner as a single enhancement-mode III-N device.

The III-N device 201 of FIG. 2A differs from the III-N device 101 of FIG. 1A in that the III-N device 201 includes an engineered III-N buffer structure 220 to increase the drain-to-substrate pinch-off voltage to greater than the maximum rated operating voltage of the device. Engineered III-N buffer structure 220 can include a nucleation layer 221, such as AlN grown at low-temperature, high-temperature or a stack thereof. III-N buffer structure 220 can future include a high aluminum composition III-N layer 222 (such as Al_{80%} Ga_{20%} N) and a medium aluminum composition III-N layer 223 (such as Al_{60%} Ga_{40%} N). For example, layer 222 can have an AlₓGa₁₋ₓNratio where 70%<x<90% and layer 223 can have an AlₓGa₁₋ₓNratio where 40%<x<70%. Layers 222 and 223 can have a thickness between 0.2 μm and 1.0 μm. For example, high aluminum composition III-N layer 222 can have a thickness of ˜0.5 μm and the medium aluminum composition III-N layer 223 can have a thickness of ˜ 0.6 μm. III-N buffer structure 220 can further include III-N stacks 224/225 where stacks 224/225 are structures comprising repetitive stacked layers of AlN/GaN, AlN/AlxGa₁₋ₓN or AlₓGa₁₋ₓN/GaN or any combination thereof. For example, the III-N stack 224 can be between 0.5 μm and 1.5 μm thick, comprising of a repetition of AlN/AlₓGa₁₋ₓN stacked layers, where AlN layers can be between 0.5 nm and 5 nm thick and the AlₓGa₁₋ₓN layers can be between 10 nm and 50 nm thick with x composition between 5% and 20%. The III-N stack 225 can be between 0.5 μm and 1.5 μm thick, comprising of a repetition of AlN/GaN stacked layers, where AlN layers can be between 0.5 nm and 5 nm thick and the GaN layers can be between 10 nm and 50 nm thick. The III-N stacks 224/225 can be doped with iron, carbon or other deep-donor or deep-acceptor agents to prevent the formation of parasitic 2DEG and 2DHG at the interfaces between the AlN/GaN, AlN/AlₓGa₁₋ₓN or AlₓGa₁₋ₓ N/GaN layers.

The engineered III-N buffer structure 220 can increase the drain-to-substrate pinch-off voltage compared to a standard III-N buffer layer 11 described in FIG. 1A. For example, the drain-to-substrate pinch-off voltage can be greater than 750V and the maximum rated drain-to-source operating voltage can be less than 750V. Implementation of the buffer structure 220 can prevent the total depletion of the 2DEG channel 19′ in the area below the drain electrode extending portion 17′, preventing the forward bias of the gate dielectric layer 14 and/or the insulating layer 15 to reducing negative charge trapping and current degradation. The engineered III-N buffer structure 220 can be less than 6 μm thick. The engineered III-N material structure can have a breakdown voltage of greater than 750V.

To measure the impact of 2DEG depletion and current collapse caused by back-gating effect and subsequent trapping of electrons in the into the dielectric layer 14 and/or the insulating layer 15 below the drain electrode extending portion 17′, a test circuit can be used as shown in FIG. 2B. A simplified circuit schematic 210 which does not require connecting the gate electrode 18 (not shown in FIG. 2B for simplicity) is used. Also, engineered III-N buffer structure 220 is not shown for simplicity. The drain-to-source potential is set to a low voltage (e.g., 1V), a first drain-source current is measured, and a first on-state resistance is calculated. The magnitude of the drain-source current gives an indication of the 2DEG channel density. The voltage between the drain electrode 17 and the substrate 10 is swept (sweep 1) from 0V to the maximum drain-to source operating voltage (VTR (DSS)) of the device while the current between the drain and source is measured (Ips). The rate of voltage sweep can be greater than 1 V/s. Since the VDs is held constant, to increase the drain-to-substrate potential during the test, the voltage of the substrate 10 is swept to negative values with respect to the voltage of the drain electrode 17. The drain-to-substrate voltage can be held at VTR (DSS) for a minimum time of 2 minutes. This hold time is to insure sufficient operational stress on the device. Next, the substrate voltage is swept (sweep 2) back to 0V, a second drain-source current is measured, and a second on-state resistance is calculated. For the purpose of this specification, it is assumed that the first drain-source current measurement and the second drain-source current measurement are completed within 1 hr of each other.

FIGS. 2C and 2D show graphical data comparing measured results of actual back-gating measurements between a device fabricated in accord with device 101 of FIG. 1A and a device fabricated in accord with device 201 of FIG. 2A. Referring to FIG. 2C specifically, the drain-to-substrate voltage is gradually increased from 0 V to the maximum rated voltage 252 (VTR (DSS)=e.g., 725 V) (forward sweep 250) and gradually decreased from VTR (DSS) to 0 V (backward sweep 251). The drain-source current is recorded during both forward sweep 250 and backward sweep 251. During the forward sweep 250, the drain-source current reaches 0 A around 600V, indicating back-gating pinch-off 253 and full 2DEG depletion before VD-SUB reaches VTR (DSS). This situation leads to forward-bias of the dielectric layer 14 and the insulating layer 15 below the drain electrode extending portion 17 and charge trapping into the dielectric layer 14 and/or the insulating layer 15 below the drain electrode extending portion 17′ resulting in severe current degradation as observed in the backward sweep 251. As seen in FIG. 2C, the starting Id is ˜ 0.05A/mm and the ending Id is ˜0.015A/mm which indicates a current reduction of more than 50% and an on-state resistance increase of more than 100%.

FIG. 2D shows the back-gating test results on a device fabricated in accord with device 201 with engineered III-N buffer structure 220. As seen in FIG. 2D, the 2DEG is never fully depleted (VD-SUBpinch-off >VTR (DSS)) as indicated by the current >OA when the voltage sweep reaches 252. The charge trapping mechanism is prevented and virtually no current degradation is observed with device 201. However, engineered III-N buffer structures such as that of structure 220 can be expensive and time consuming to develop. In addition, engineered III-N buffer structures such as that of structure 220 do not prevent the charge trapping issue below the drain electrode extending portion 17′ if the 2DEG is fully depleted because of build-up of lateral electric field due to capacitive coupling between the drain electrode 17 and the gate electrode 18. This scenario can happen in devices with aggressive design with highly scaled gate drain-side access region 27, targeted to reduce specific on-state resistance and overall chip-size. Therefore, other solutions may be desirable.

FIG. 2E shows box-plot data of additional test results which also shows the performance of a device fabricated in accord with device 201. FIG. 2E shows the on-resistance (i.e., Ron) increase over time of a specific stress test. A device fabricated in accord with device 201 was subjected to a High Temperature Reverse Bias (i.e., HTRB) test. The test conditions were as such: the source-to-drain voltage was biased at 750V while the gate-to-source voltage is biased less than the threshold voltage; Temperature is held at 175° C.; voltage is held for 1,000 hours. The test is performed as follows. The on-resistance of the device is measured before HRB (time=0), next the HTRB stress is performed, and the on-resistance of the device is measured again at intervals of 250 hours, 500 hours, and 1000 hours. The on-resistance (Ron) is plotted in FIG. 2E. As seen in FIG. 2E, the median on-resistance increase of the device at time 0 is ˜30mΩ. After 250 hours of HTRB stress, the median on-resistance is increased but is still below 35mΩ and below a 20% increase in on-resistance. After 500 hours and 1000 hours of stress, respectively, the median on-resistance is still below 35mΩ and all of devices tested had less than 20% increase in on-resistance after HTRB stress under the previously described conditions. These results validate the effectiveness of the invention.

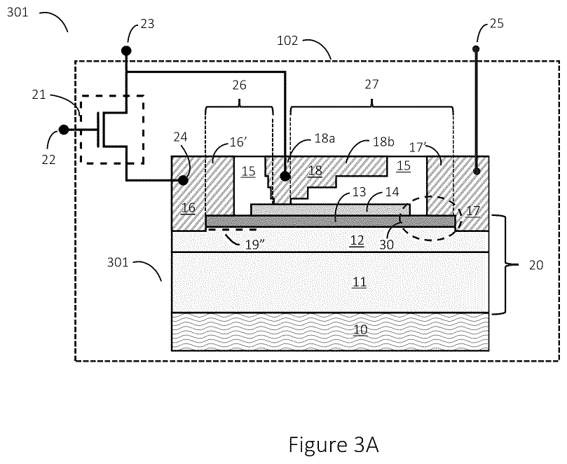

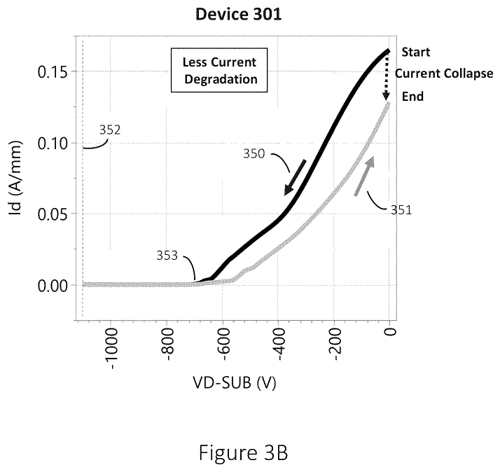

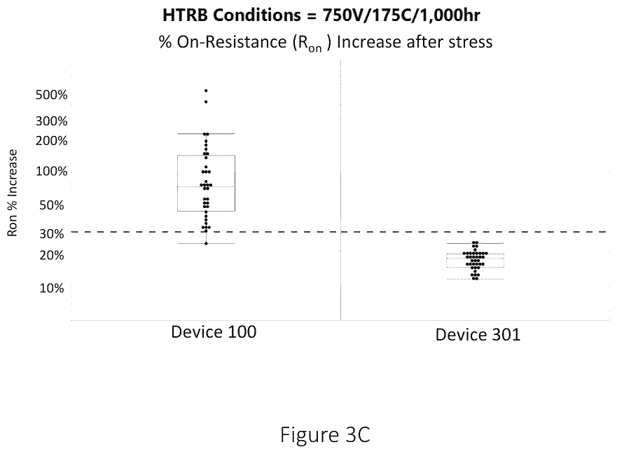

FIG. 3A shows a cross-sectional view of a III-N device 301 which is similar to the III-N device 101 of FIG. 1A. III-N device 301 can be an enhancement-mode device (i.e., normally-off) or a depletion-mode device (i.e., normally-on). In the case that device 301 is a depletion-mode device (D-mode), device 301 can be in a cascode configuration with a low-voltage enhancement-mode device 21 (e.g., a silicon-FET), to form a normally-off hybrid device 300 which can operate in a similar manner as a single enhancement-mode III-N device.

The III-N device 301 of FIG. 3A is different from the III-N device 101 of FIG. 1A in that III-N device 301 does not include the gate dielectric layer 14 and/or the insulating layer 15 formed below the drain electrode extending portion 17′ as shown in dashed region 30. Instead, the drain electrode extending portion 17′ is formed “on” and in direct contact with the second side of the III-N barrier layer 13. Furthermore, the III-N device 301 can optionally not include the gate dielectric layer 14 and/or the insulating layer 15 formed below the source electrode extending portion 16′. Instead, the source electrode extending portion 16′ is formed on and in direct contact with the second side of the III-N barrier layer 13. By removing the gate dielectric layer 14 and/or the insulating layer 15 below the extending portions 16′/17′, negative charge can no longer be trapped, thereby eliminating or reducing the current degradation. Since the insulating material which is responsible for the charge trapping in FIG. 1A is absent, the 2DEG channel can be fully depleted all the way to the drain electrode by the substrate without causing current degradation. Therefore, a device can be fabricated having a substrate-to-drain pinch off voltage that is lower than the maximum operating voltage of the device, without causing performance problems.

Although not shown for simplicity, device 301 can also include a conductive inter-layer formed between the drain and/or source extending portions 16′/17′ and the III-N barrier layer 13. The inter-layer can be an etch-stop layer to assist with the manufacturing process of the source and/or drain electrodes. The etch-stop layer can have an etch rate that is less than that of the source and/or drain electrodes when etched under similar conditions. The etch stop layer should be a conductive material to allow for a path for charge to move between the drain electrode and the III-N barrier layer. The etch stop layer can b, for example, TIN, TiW, Ni or silicon (e.g., sputtered Silicon). The etch stop layer can have a thickness between 5 nm and 100 nm. The etch stop layer can have a thickness less than 100 nm.

FIG. 3B shows the back-gating test results on device 301 with modified drain electrode region 17′. The drain-to-substrate voltage is gradually increased from 0 V to the maximum rated voltage 352 (VTR (DSS)=e.g., 1100 V) (forward sweep 350) and gradually decreased from VTR (DSS) to 0 V (backward sweep 351). The drain-source current is recorded during both forward sweep 350 and backward sweep 351. During the forward sweep 350, the drain-source current reaches 0 A around 650V, indicating back-gating pinch-off 353 and full 2DEG depletion before VD-SUB reaches VTR (DSS). As seen in FIG. 3B, the VTR (DSS) 352 is more than 100V away VD-SUB 353. However, since the dielectric layer 14 and/or the insulating layer 15 are not present below the drain electrode extending portion 17′, the charge trapping mechanism is prevented resulting in significant reduction in current degradation. As seen in FIG. 3B, the starting Id is ˜ 0.155A/mm and the ending Id is ˜0.125A/mm which indicates a current reduction of less than 20% and an on-state resistance increase of less than 25%. This result demonstrates a significant improvement in performance compared to the results of device 101 shown in FIG. 2C.

This result was unexpected. As previously mentioned, the drain electrode extending portion 17 can be typically 0.5 μm in length and range between 0.25 μm-1.0 μm in length. In a high-voltage III-N power device such as device 101 this represents less than 2% of the total source-to-drain spacing. At the time of this invention, it was not obvious that such a small area of drain/insulator overlap could contribute to such a large current degradation. However, the results shown in FIG. 3B clearly show that current collapse can be reduced.

FIG. 3C shows a box-plot diagram of test results which also shows the performance benefit of a device fabricated in accord with device 301 of FIG. 3A compared to a device fabricated in accord with device 100 of FIG. 1A. FIG. 3C shows the percentage on-resistance (i.e., Ron) increase after a specific stress test. Device 301 and device 100 were subjected to a High Temperature Reverse Bias (i.e., HTRB) test. The test conditions were as such: the source-to-drain voltage is biased at 750V while the gate-to-source voltage is biased less than the threshold voltage; the temperature is held 175° C.; The voltage bias is held for 1,000 hours. The test is performed as follows. The on-resistance of the devices are measured before HTRB stress, next the HTRB test is performed, and the on-resistance of the device is measured again (post HTRB). As seen in FIG. 3C, the median on-resistance increase of device 100 is greater than 70%. However, when device 301 was tested under the same conditions, the median on-resistance increase was less than 20% and all of the devices demonstrated a post HTRB on-resistance increase of less than 30%. These results validate the effectiveness of the invention.

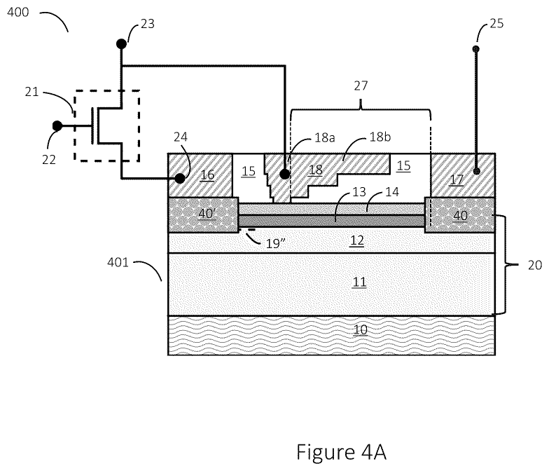

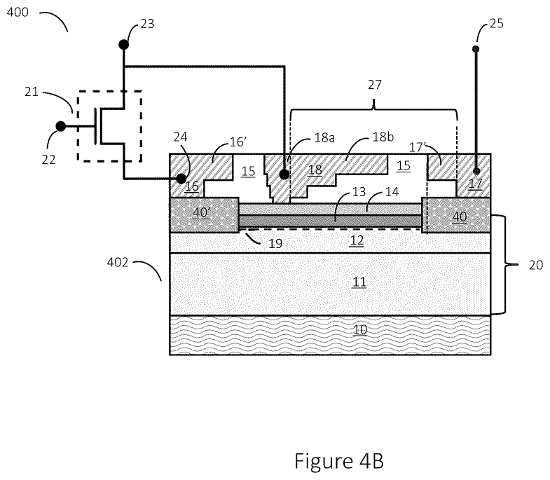

FIG. 4A shows a cross-sectional view of a III-N device 401 which is similar to the III-N device 301 of FIG. 3A. III-N device 401 can be an enhancement-mode device (i.e., normally-off) or a depletion-mode device (i.e., normally-on). In the case that device 401 is a depletion-mode device (D-mode), device 401 can be in a cascode configuration with a low-voltage enhancement-mode device 21 (e.g., a silicon-FET), to form a normally-off hybrid device 400 which can operate in a similar manner as a single enhancement-mode III-N device. III-N device 401 differs from III-N device 301 in that device 401 includes an n-type III-N contact layer 40 formed below the drain electrode 17 and n-type III-N contact layer 40′ formed below the source electrode 16. N-type III-N contact layer 40/40′ can be formed by implantation or by regrowth using dopants such as silicon. The source and drain electrode 16 and 17 form an ohmic contact with the n-type III-N contact layer 40/40′, which can be a high quality ohmic contact with very low electrical resistance. The length of the n-type contact layer 40 can be greater than the length of the drain electrode 17 (both measured along the channel length). The n-type contact layer 40 can include a first portion which is directly below and in ohmic contact with the drain electrode 17 and a second portion which extends into the drain side access region 27, such that there is no drain electrode extending portion 17′ in device 401. When the n-type III-N contact layer 40 extends into the drain side access region and the drain electrode extending portion is eliminated, as shown in FIG. 4A, charge trapping can be eliminated near the drain electrode and current collapse can be reduced.

FIG. 4B shows a cross-sectional view of a III-N device 402 which is similar to the III-N device 101 of FIG. 1A. However, III-N device 402 includes the drain extending portion 17′ and the source electrode extending portion 16′. N-type III-N contact layer has a first end which extends into the drain-side access region 27 towards the gate electrode 18. The first end of the n-type III-N layer 40 extends further into the drain-side access region than the drain electrode extending portion 17′. A first end of the n-type III-N layer 40′ extends towards the gate 18 further than the source electrode extending portion 16′. The 2DEG channel 19 extends between the first end of n-type III—N layer 40′ and the first end of n-type III-N layer 40. As such, no portion of the 2DEG channel 19 is formed under either the source or drain electrode extending portions 16′ or 17′. As seen in FIG. 4B insulator layer 15 can be formed between the drain electrode extending portion 17′ and the n-type III-N layer 40, however negative charge trapping in the insulating layer 15 below portion 17′ will is prevented due to the device design being free of the 2DEG channel below the extending portions and current degradation will be prevented.

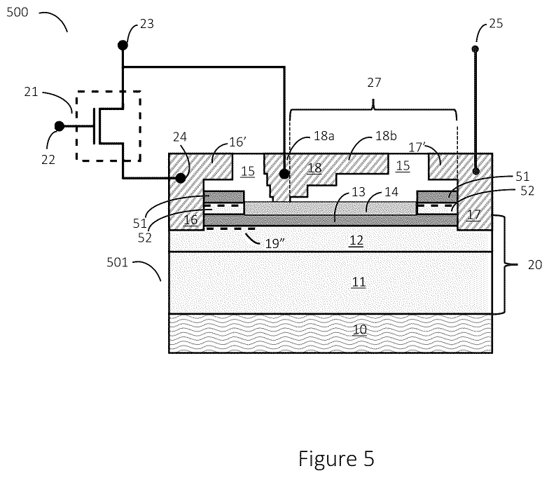

FIG. 5 shows a cross-sectional view of a III-N device 501 which is similar to the III-N device 101 of FIG. 1A. III-N device 501 can be an enhancement-mode device (i.e., normally-off) or a depletion-mode device (i.e., normally-on). In the case that device 501 is a depletion-mode device (D-mode), device 501 can be in a cascode configuration with a low-voltage enhancement-mode device 21 (e.g., a silicon-FET), to form a normally-off hybrid device 500 which can operate in a similar manner as a single enhancement-mode III-N device. III-N device 501 differs from III-N device 101 in that device 501 includes a second 2DEG channel under the drain electrode extending portion 17′ and optionally a second 2DEG channel under the source electrode extending portion 16′. The second 2DEG channel is induced from a compositional mismatch between a second III-N channel layer 52 and a second III-N barrier layer 51. Layer 51 and layer 52 can be initially formed or grown continuous over the first III-N barrier layer 13 and extend between the drain electrode 17 and the source electrode 16. Then the second channel layer 52 and the second barrier layer 51 can be removed or etched away in a region that is inset from the source extending portion 16′ and the drain extending portion 17′ such that the remaining ends of layer 51/52 is closer towards the gate electrode 18 than the extending portions 16′/17′. The gate dielectric 14 can be formed the inset region. Forming a second 2DEG channel below the extending portion will shield the portion of insulating layer 15 which is below the drain electrode extending portion 17′ from becoming forward-biased when the primary 2DEG channel 19 is fully depleted. Furthermore, the second 2DEG channel formed in the second channel layer will increase the drain-to-substrate pinch-off voltage substantially. This will prevent the primary 2DEG channel 19 from becoming fully depleted under the drain extending portion 17′ when device 501 is operated at the maximum rated drain-to-source voltage.

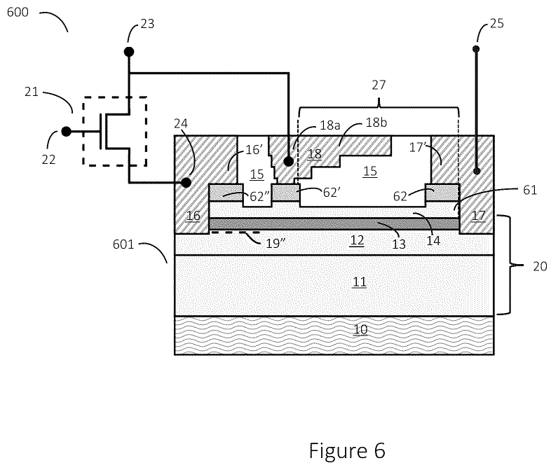

FIG. 6 shows a cross-sectional view of a III-N device 601 which is similar to the III-N device 101 of FIG. 1A. III-N device 601 can be an enhancement-mode device (i.e., normally-off) or a depletion-mode device (i.e., normally-on). In the case that device 601 is a depletion-mode device (D-mode), device 601 can be in a cascode configuration with a low-voltage enhancement-mode device 21 (e.g., a silicon-FET), to form a normally-off hybrid device 600 which can operate in a similar manner as a single enhancement-mode III-N device. III-N device 601 differs from III-N device 101 in that device 601 includes a III-N spacer layer 61 (e.g., UID GaN) and a p-type III-N layer 62 formed over the III-N channel layer 13. Portions of the p-type III-N layer 61 can be etched away in the source and drain access regions. Remaining portion 62 is directly below and in contact with drain extending portion 17′. Portion 62′ is directly below and in contact with the gate electrode 18. Portion 62″ is directly below and in contact with the source electrode extending portion 61′. A first end of remain portion 62 extends further towards the gate electrode 18 in the drain-side access region 27 than the drain extending portion 17′ and a first end of remaining portion 62″ extends further towards the gate electrode 18 than the source side extending portion 16′. The III-N spacer layer 61 acts as a diffusion barrier to prevent/limit the p-type dopant of III-N layer 62 from reducing the 2DEG channel charge. The device can be free of a gate dielectric layer 14 as shown in device 101 of FIG. 1A. Forming the gate dielectric 14 is typically grown in-situ in a MOCVD reactor, and causes significant maintenance and through put issues for the MOCVD too. Having a device which is free of a gate dielectric can greatly reduce the cost and time of the fabrication process. Device 601 is a JFET type device.

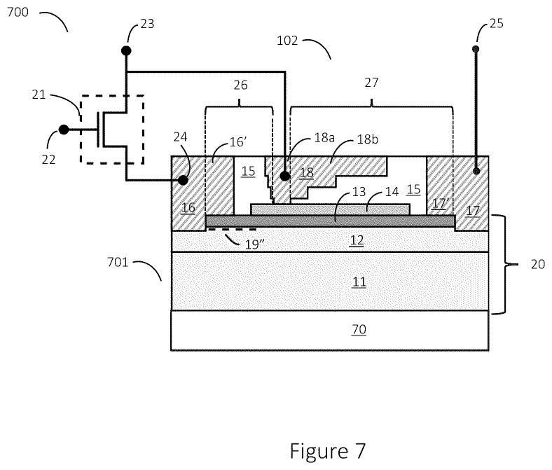

FIG. 7 shows a cross-sectional view of a III-N device 701 which is similar to the III-N device 301 of FIG. 3A. III-N device 701 can be an enhancement-mode device (i.e., normally-off) or a depletion-mode device (i.e., normally-on). In the case that device 701 is a depletion-mode device (D-mode), device 701 can be in a cascode configuration with a low-voltage enhancement-mode device 21 (e.g., a silicon-FET), to form a normally-off hybrid device 700 which can operate in a similar manner as a single enhancement-mode III-N device. III-N device 701 differs from III-N device 301 in that the III-N material structure 20 is formed on an insulating substrate 70 (e.g., a sapphire or SiC substrate) instead of the conductive silicon substrate 10 described in FIG. 3A. The device 101 of FIG. 1A can also be fabricated on an insulating substrate such as substrate 70, however severe current degradation can occur. An insulating substrate is beneficial for reducing electric fields in the buffer layers and realizing high voltage lateral GaN HEMT devices with rated voltage >650V, for example greater than 1200V, without the need for thick epitaxial III-N buffer layer growth (such as buffer layer 11). However, such devices require a lateral high-voltage blocking region that can increase die size and therefore die cost. One method to reduce die size is to increase the 2DEG channel charge density, however this can cause reliability issues due to increased electric fields. Another method is to reduce the length (measured along the channel length) of the drain side access region 27. This increases the capacitive coupling between gate electrode 18 and drain electrode 17. As a result of this increased coupling, when high voltage is applied to the drain terminal, the 2DEG can become fully depleted resulting in negative charge trapping in layers 14 and/or 15 under the drain electrode extending portion 17′. This can cause Ron of the device to increase therefore increasing the current degradation under operation. A device 701 shown in FIG. 7, where layers 14 and/or 15 are eliminated below the drain electrode extending portion 17′ can address this potential problem and help realize reliable and low cost high voltage lateral GaN devices on insulating substrates.

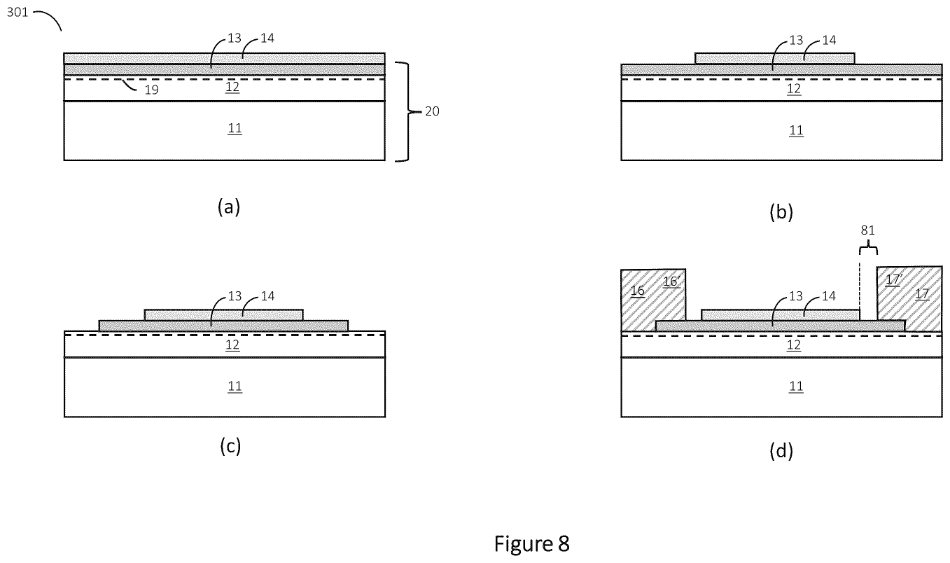

FIGS. 8 (a)-(d) shows a method of fabrication for the device 301 of FIG. 3A. Shown in FIG. 8 (a), a III-N material structure is formed on a substrate (not shown). The III-N material structure includes a III-N buffer layer 11 (e.g., AlGaN/GaN), III-N channel layer 12 (e.g., UID GaN), and a III-N barrier layer 13 (e.g., AlGaN). Gate dielectric layer 14 is formed continuously over the top surface of the III-N material structure. Shown in FIG. 8 (b) the gate dielectric layer is removed or etched (e.g., dry etched in an area where the source and drain electrodes will be formed. As shown in FIG. 8 (c) a portion of the III-N barrier layer can be removed or etch away to form a recess. The remaining portion of the gate dielectric layer 14 is smaller than the remaining portion of the III-N channel layer 13. The recess formed in the III-N barrier layer can help to improve the ohmic contact of the source/drain connection to the 2DEG. As seen in FIG. 8 (d). Source electrode 16 and drain electrode 17 are formed in the removed portion of the III-N barrier 13. Drain extending portion 17′ and source extending portion 16′ are formed over a top surface of the III-N barrier layer 13. The device can further be annealed at high temperatures (e.g., greater than 500C) to form the ohmic contact to the 2DEG. Separation 81 is between the end of the extending portion 17′ and the end of the gate dielectric layer 14 closest to the drain electrode 17. Separation 81 can be between 0.1-2 μm but is ideally kept as small as possible.

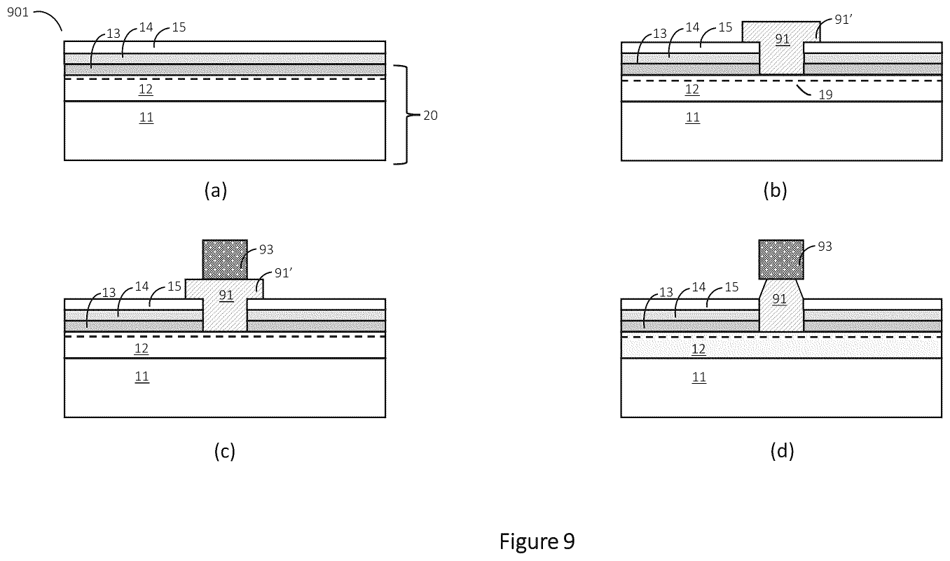

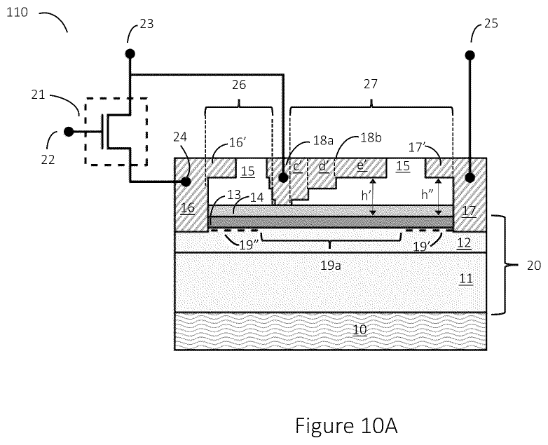

FIGS. 9 (a)-(d) shows a method 901 of fabricating a drain electrode 91 which is free of the drain electrode extending portion 17′ shown in FIG. 1A. Shown in FIG. 9 (a), a III-N material structure is formed on a substrate (not shown). The III-N material structure includes a III-N buffer layer 11 (e.g., AlGaN/GaN), III-N channel layer 12 (e.g., UID GaN), and a III-N barrier layer 13 (e.g., AlGaN). Gate dielectric layer 14 is formed continuously over the top surface of the III-N material structure20. Insulating layer 15 is formed continuously over the top surface of the gate dielectric layer 14.

As shown in FIG. 9 (b), a recess is formed (e.g., by dry-etching) in the insulating layer 15, the dielectric layer 14 and the III-N barrier layer 13. A metal contact layer (e.g., Ti/Al) is deposited within the recess and continuously over the top surface of the insulating layer 15. Then the metal contact layer is patterned and etched to form drain electrode 91 with drain electrode extending portion 91′. The drain electrode 19 is patterned in such a way that the top width of the drain is larger than the width of the recess in order to guarantee good metal coverage within the recess and a high quality ohmic contact of the drain electrode to the 2DEG channel 19. The insulating layer 15 is used to protect the gate dielectric layer 14 during the metal etching step used to form the drain electrode 91.

However, as previously discussed, having an insulating material between the drain electrode extending portion 91′ and the 2DEG channel 19 can cause negative charge trapping and current degradation. Another method to reduce this current degradation is to remove the drain extending portion 19′. As seen in FIG. 9 (c) a photoresist layer 93 is patterned over the drain electrode 91 and inset from the drain electrode extending portion 91′.

Then, as seen in FIG. 9 (d), the device is subjected to an isotropic chemical wet etch process which is selective to the drain electrode metal stack. The corners of the drain extending portion 19′ etch at a faster rate than the sidewall creating a re-entrant profile under the photoresist layer 93. Then the photoresist layer 93 is removed and a drain electrode is formed without an overhang and current degradation is reduced. Although the process 901 shown in FIGS. 9 (a)-(c) describes a method of forming a drain electrode, the same process can be used simultaneously to form a source electrode which is free of an extending portion.

Alternatively, another embodiment and method of fabrication can be used to achieve similar performance improvements to those described in device 301. Although device 301 of FIG. 3A shows the drain extending portion 17′ in direct contact with the III-N barrier layer 13, improved on-resistance has also been shown by substantially increasing the thickness of the insulating portion 15 that is formed below the drain extending portion 17′.

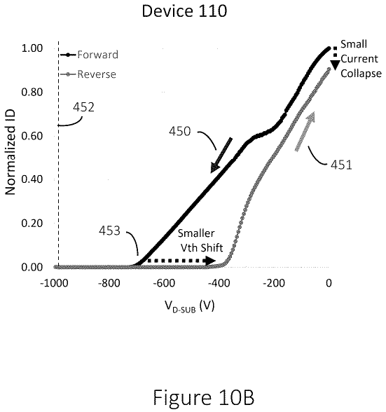

FIG. 10A shows a cross-sectional view of a III-N device 110 which is similar to the III-N device 100 of FIG. 1A. III-N device 110 can be an enhancement-mode device (i.e., normally-off) or a depletion-mode device (i.e., normally-on). In the case that device 110 is a depletion-mode device (D-mode), device 110 can be in a cascode configuration with a low-voltage enhancement-mode device 21 (e.g., a silicon-FET), to form a normally-off hybrid device 700 which can operate in a similar manner as a single enhancement-mode III-N device. III-N device 110 differs from III-N device 100 in that the thickness of the insulating portion 15 and/or 14, which is formed below the drain extending portion 17″ is substantially increased compared to device 100 of FIG. 1A. For example, the total thickness of the insulating material (i.e., layer 14 plus layer 15) which is formed under the drain extending portion of device 100 can be less than 100 nm. However, in device 110 the total thickness of the insulating material which is formed under the drain extending portion 17′ can be more than 500% greater than compared to device 100. The total thickness of the insulating material can be greater than 300 nm, greater than 500 nm, for example between 500 nm and 1,000 nm.

As shown in FIG. 10A, device 110 includes multi-field plate structure 18b. The field plate structure 18b includes a first portion c′ (i.e., 1st Field Plate), a second portion d′ (i.e., 2nd Field Plate) and a third portion e′ (i.e., 3rd Field Plate) where each field plate has an increasing step height between the respective field plate and the top of the III-N barrier layer 13 as the field plate extends towards the drain electrode. The 3rd Field Plate e′ has a step height h′ above the barrier layer 13. The step height h″ of the drain overhang 17′ of device 110 is at least equal to or greater than the step height h′ of the 3rd Field plate. Device 110 can also have more than three field plates, for example, device 110 can have four field plates (not shown) and the step high h″ can be less than the 4th field plate step height, but greater than the 3rd field plate step height.

FIG. 10B shows the back-gating test results on device 110. The drain-to-substrate voltage is gradually increased from 0 V to the maximum rated voltage 452 (VTR (DSS)=e.g., 1000 V) (forward sweep 450) and gradually decreased from VTR (DSS) to 0 V (backward sweep 451). The drain-source current is recorded during both forward sweep 450 and backward sweep 451. During the forward sweep 450, the drain-source current reaches 0 A around 650V, indicating back-gating pinch-off 453 and full 2DEG depletion before VD-SUB reaches VTR (DSS). As seen in FIG. 10B, the VTR (DSS) 452 is more than 100V away VD-SUB 453. However, since the dielectric layer 14 and/or the insulating layer 15 are relatively thick below the drain electrode extending portion 17′, the charge trapping mechanism is reduced resulting in significant improvement in current degradation. As seen in FIG. 10B, the starting normalized Id is 1 and the ending Id is ˜0.9 which indicates a current reduction of less than 20% and an on-state resistance increase of less than 25%. This result demonstrates a significant improvement in qperformance compared to the results of device 101 shown in FIG. 2C.

A number of implementations have been described. Nevertheless, it will be understood that various modifications may be made without departing from the spirit and scope of the techniques and devices described herein.

What is claimed is:

1. A III-N device, comprising:
a conductive substrate; and
a III-N material structure comprising a III-N buffer layer, a III-N channel layer and a III-N barrier layer, wherein the compositional difference between the III-N channel layer and the III-N barrier layer induces a 2DEG channel therein;
a source electrode, a gate electrode, and a drain electrode; wherein
the gate electrode is electrically connected to the conductive substrate, and comprises a first field plate, a second field plate, and a third field plate;
the first field plate is a step first height above the III-N barrier layer, the second field plate is a second step height above the III-N barrier layer, and the third field plate is a third step height above the III-N barrier layer, wherein the second step height is greater than the first step height, and the third step height is greater than the second step height;
the drain electrode comprises a first portion and a second portion;
the first portion of the drain electrode is in ohmic contact with the 2DEG channel, and the second portion of the drain electrode extends over a top surface of the III-N barrier layer and is a fourth step height above the III-N barrier layer; wherein
the fourth step height is equal to or greater than the third step height.

2. The III-N device of claim 1, wherein the device further comprises an insulating layer formed between the top surface of the III-N barrier layer and the second portion of the drain electrode.

3. The III-N device of claim 2, wherein the device is intentionally free of any dielectric or insulating material between the drain electrode and the III-N material structure.

4. The III-N device of claim 1, wherein the device has a maximum rated drain-to-source operating voltage of greater than 600V and a drain-to-substrate pinch-off voltage of less than 600V.

5. The III-N device of claim 4, wherein the device has a first on-state resistance when the drain-to-source voltage is held constant at a low voltage, wherein the device has a second on-state resistance upon the drain-to-substrate voltage being swept from the low voltage to the maximum rated drain-to-source voltage and back to the low voltage, and the first on-state resistance is within 25% of the second on-state resistance.

6. The III-N device of claim 4, wherein an Ips of the first on-state resistance is within 20% of an Ips of the second on-state resistance.

7. The III-N device of claim 1, wherein the source electrode comprises a first portion and a second portion, the first portion is in ohmic contact with the 2DEG channel and the second portion extends over the top surface of the III-N barrier layer and the second portion has a fifth step height that is equal to or greater than the third step height.

8. The III-N device of claim 1, wherein the devices comprises a fourth field plate having a sixth step height above the III-N material layer, wherein the sixth step height is greater than the fourth step height.

9. The III-N device of claim 7, wherein the device is a depletion-mode device and an enhancement-mode low-voltage Si-FET is arranged in a cascode configuration to form a hybrid enhancement-mode III-N device.

10. The III-N device of claim 1, wherein when the drain-to-source voltage is at the maximum rated operating voltage, the 2DEG channel below the second portion of the drain electrode is depleted from a vertical electric field between the drain electrode and the conductive substrate.

11. A III-N device, comprising:
a conductive substrate; and
a III-N material structure comprising a III-N buffer layer, a III-N channel layer and a III-N barrier layer, wherein the compositional difference between the III-N channel layer and the III-N barrier layer induces a 2DEG channel therein;
a source electrode, a gate electrode, and a drain electrode; wherein
the gate electrode is electrically connected to the conductive substrate; and
a gate dielectric layer having a first thickness, is between the gate electrode and the III-N barrier layer;
the drain electrode comprises a first portion and a second portion;
the first portion of the drain electrode is in ohmic contact with the 2DEG channel, and the second portion of the drain electrode extends over a top surface of the III-N barrier layer and an insulating layer having a second thickness, is between the second portion of the drain electrode and the III-N barrier layer; wherein
the second thickness of the insulating layer is more than 500% the first thickness of the gate dielectric layer.

12. The III-N device of claim 11, wherein the second thickness of the insulating layer is greater than 300 nm.

13. The III-N device of claim 11, wherein the device has a maximum rated drain-to-source operating voltage is at least 650V and a drain-to-substrate pinch-off voltage is 600V or less.

14. The device of claim 11, wherein an Ips of the first on-state resistance is within 20% of an Ips of the second on-state resistance.

15. The device of claim 11, wherein the 2DEG channel is fully depleted of charge below the second portion of the drain electrode when the III-N device is biased at the maximum rated drain-to-source pinch-off voltage.

16. The III-N device of claim 11, wherein the second thickness of the insulating layer is between 500-1,000 nm.
